(19) United States
(12) Patent Application Publication
(10) Pub. No.: US 2013/0313639 A1
(43) Pub. Date: Nov. 28, 2013

(54) SEMICONDUCTOR DEVICE

(71) Applicant: KABUSHIKI KAISHA TOSHIBA, Tokyo (JP)

(72) Inventor: Koji SHIRAI, Iwate-ken (JP)

(73) Assignee: KABUSHIKI KAISHA TOSHIBA, Tokyo (JP)

(21) Appl. No.: 13/781,707

(22) Filed: Feb. 28, 2013

(30) Foreign Application Priority Data
May 24, 2012 (JP) 2012-118670

(51) Int. Cl. H01L 29/78

(52) U.S. Cl. CPC H01L 29/7816; H01L 29/78
USPC 257/335; 257/288

(57) ABSTRACT

According to one embodiment, a semiconductor device includes a semiconductor substrate of a first conductivity type, a first semiconductor layer of a second conductivity type provided on the semiconductor substrate, a second semiconductor layer of the first conductivity type provided on the first semiconductor layer, a first well of the second conductivity type provided on the second semiconductor layer, a second well of the first conductivity type provided on part of the first well, a source layer of the second conductivity type provided on part of the second well and separated from the first well, a back gate layer of the first conductivity type provided on another part of the second well, and a drain layer of the second conductivity type provided on another part of the first well. The second semiconductor layer and the second well are separated from each other by the first well.

### CROSS-REFERENCE TO RELATED APPLICATIONS

This application is based upon and claims the benefit of priority from the prior Japanese Patent Application No. 2012-118670, filed on May 24, 2012; the entire contents of which are incorporated herein by reference.

### FIELD

Embodiments described herein relate generally to a semiconductor device.

### BACKGROUND

Conventionally, a technique for forming an n-channel MOSFET (metal-oxide-semiconductor field-effect transistor) on a p-type semiconductor substrate has been known. In this technique, to isolate the MOSFET from other device elements, an n-type semiconductor layer is formed on the p-type semiconductor substrate. Then, a p-type well and n-type source layer and drain layer are formed thereon. Furthermore, to increase the breakdown voltage, a p-type RESURF layer may be formed on the n-type semiconductor layer. In this case, parasitic transistors are formed in the stacked structure from the p-type semiconductor substrate to the n-type drain layer. Depending on the operation of the MOSFET, these parasitic transistors may be turned on, and a parasitic current may flow from the semiconductor substrate to the drain layer. This may vary the potential of the semiconductor substrate and affect the operation of other device elements.

### BRIEF DESCRIPTION OF THE DRAWINGS

FIG. 1 is a sectional view illustrating a semiconductor device according to a first embodiment;

FIG. 2 is a circuit diagram illustrating an H switch including the semiconductor device according to the first embodiment;

FIG. 3A is a schematic sectional view illustrating the operation of the semiconductor device according to the first embodiment, FIG. 3B is an equivalent circuit diagram of FIG. 3A;

FIG. 4 is a sectional view illustrating a semiconductor device according to a comparative example;

FIG. 5A is a schematic sectional view illustrating the operation of the semiconductor device according to the comparative example, FIG. 5B is an equivalent circuit diagram of FIG. 5A;

FIG. 6 is a sectional view illustrating a semiconductor device according to a second embodiment;

FIG. 7 is a sectional view illustrating a semiconductor device according to a third embodiment;

FIG. 8 is a sectional view illustrating a semiconductor device according to a fourth embodiment;

FIG. 9 is a sectional view illustrating a semiconductor device according to a fifth embodiment;

FIG. 10 is a sectional view illustrating a semiconductor device according to a sixth embodiment;

FIG. 11 is a sectional view illustrating a semiconductor device according to a seventh embodiment;

FIGS. 12A and 12B illustrate simulation results of the impurity concentration distribution formed in the semiconductor device; and

FIG. 13 is a graph illustrating the simulation results of I-V characteristics.

### DETAILED DESCRIPTION

In general, according to one embodiment, a semiconductor device includes a semiconductor substrate of a first conductivity type, a first semiconductor layer of a second conductivity type provided on the semiconductor substrate, a second semiconductor layer of the first conductivity type provided on the first semiconductor layer, a first well of the second conductivity type provided on the second semiconductor layer, a second well of the first conductivity type provided on part of the first well, a source layer of the second conductivity type provided on part of the second well and separated from the first well, a back gate layer of the first conductivity type provided on another part of the second well, a drain layer of the second conductivity type provided on another part of the first well, a gate insulating film provided immediately above a portion of the second well between the first well and the source layer, a gate electrode provided on the gate insulating film, a source electrode connected to the source layer and the back gate layer, a drain electrode connected to the drain layer, and a substrate electrode connected to the semiconductor substrate. The first semiconductor layer and the second semiconductor layer are in floating state. The second semiconductor layer and the second well are separated from each other by the first well.

In general, according to one embodiment, a semiconductor device includes a semiconductor substrate of a first conductivity type, a first semiconductor layer of a second conductivity type provided on the semiconductor substrate, a second semiconductor layer of the first conductivity type provided on the first semiconductor layer, a third semiconductor layer of the second conductivity type provided on the second semiconductor layer, a first well of the second conductivity type provided on the second semiconductor layer, a second well of the first conductivity type provided on the third semiconductor layer, a source layer of the second conductivity type provided on part of the second well and separated from the first well, a back gate layer of the first conductivity type provided on another part of the second well, a drain layer of the second conductivity type provided on the first well, a gate insulating film provided immediately above a portion of the second well between the first well and the source layer, a gate electrode provided on the gate insulating film, a source electrode connected to the source layer and the back gate layer, a drain electrode connected to the drain layer, and a substrate electrode connected to the semiconductor substrate. The first semiconductor layer and the second semiconductor layer are in floating state. The second semiconductor layer and the second well are separated from each other by the third semiconductor layer.

Embodiments of the invention will now be described with reference to the drawings.

First, a first embodiment is described.

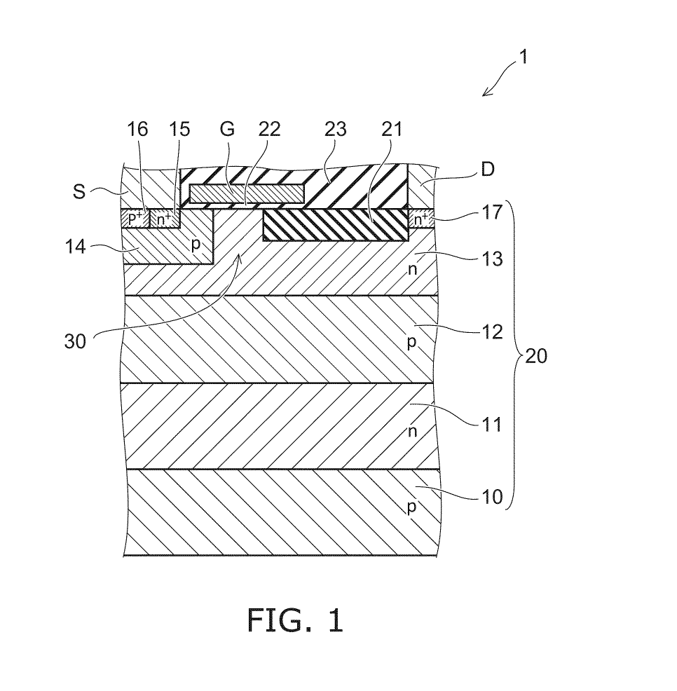

FIG. 1 is a sectional view illustrating a semiconductor device according to the embodiment.

As shown in FIG. 1, the semiconductor device 1 according to the embodiment includes a p-type substrate 10. On the p-type substrate 10, an n-type buried layer 11, a p-type RESURF layer 12, and an n-type well 13 are provided in this order from the lower side. On part of the n-type well 13, a p-type well 14 is provided. The p-type RESURF layer 12 and the p-type well 14 are separated from each other by the n-type well 13. On part of the p-type well 14, an n⁺-type source layer 15 is provided. The source layer 15 is separated from the n-type well 13 by the p-type well 14. On another part of the p-type well 14, a p⁺-type back gate layer 16 is provided. The source layer 15 and the back gate layer 16 are both in contact with the p-type well 14 and are in contact with each other. On another part of the n-type well 13, an n⁺-type drain layer 17 is provided. The drain layer 17 is in contact with the n-type well 13.

The p-type substrate 10, the n-type buried layer 11, the p-type RESURF layer 12, the n-type well 13, the p-type well 14, the source layer 15, the back gate layer 16, and the drain layer 17 are part of a semiconductor portion 20 made of e.g. monocrystalline silicon. The effective impurity concentration of the source layer 15 and the drain layer 17 is higher than the effective impurity concentration of the n-type well 13. The effective impurity concentration of the back gate layer 16 is higher than the effective impurity concentration of the p-type well 14. In this description, the “effective impurity concentration” refers to the concentration of impurity contributing to the conduction of the semiconductor material. For instance, in the case where the semiconductor material contains both impurity serving as donor and impurity serving as acceptor, the “effective impurity concentration” refers to the concentration except the amount of donor and acceptor canceling each other.

An STI (shallow trench isolation) 21 made of e.g. silicon oxide (SiO₂) is provided in a region between the p-type well 14 and the drain layer 17 on the n-type well 13. The STI 21 is penetrated into an upper portion of the semiconductor portion 20. Furthermore, a gate insulating film 22 made of e.g. silicon oxide is provided on the semiconductor portion 20 in a region extending from immediately above the portion of the p-type well 14 between the n-type well 13 and the source layer 15 through immediately above the portion of the n-type well 13 between the STI 21 and the p-type well 14 to immediately above the portion of the STI 21 on the p-type well 14 side. On the gate insulating film 22, a gate electrode G made of e.g. polysilicon doped with impurity is provided. The gate electrode G is covered with an interlayer insulating film 23 made of e.g. silicon oxide.

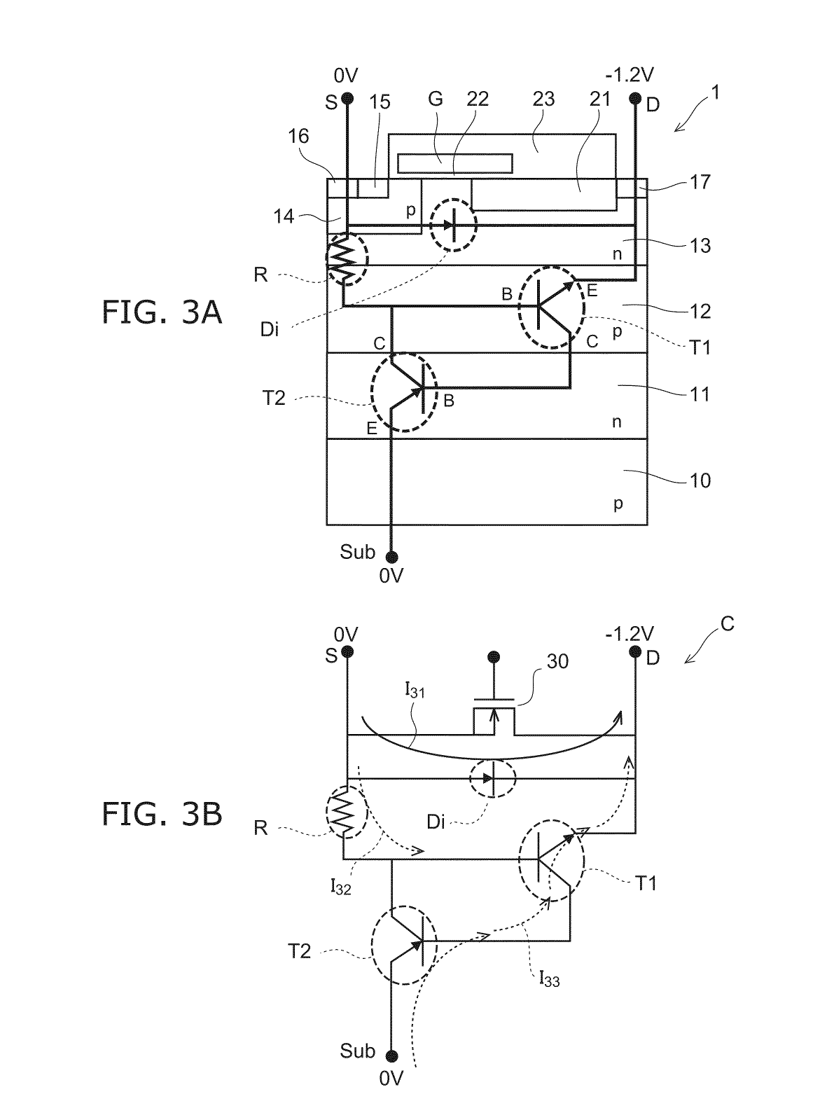

On the semiconductor portion 20, a source electrode S and a drain electrode D are provided. The source electrode S is connected to the source layer 15 and the back gate layer 16. The drain electrode D is connected to the drain layer 17. Furthermore, the semiconductor device 1 includes a substrate electrode Sub (see FIG. 3A), which is connected to the p-type substrate 10.

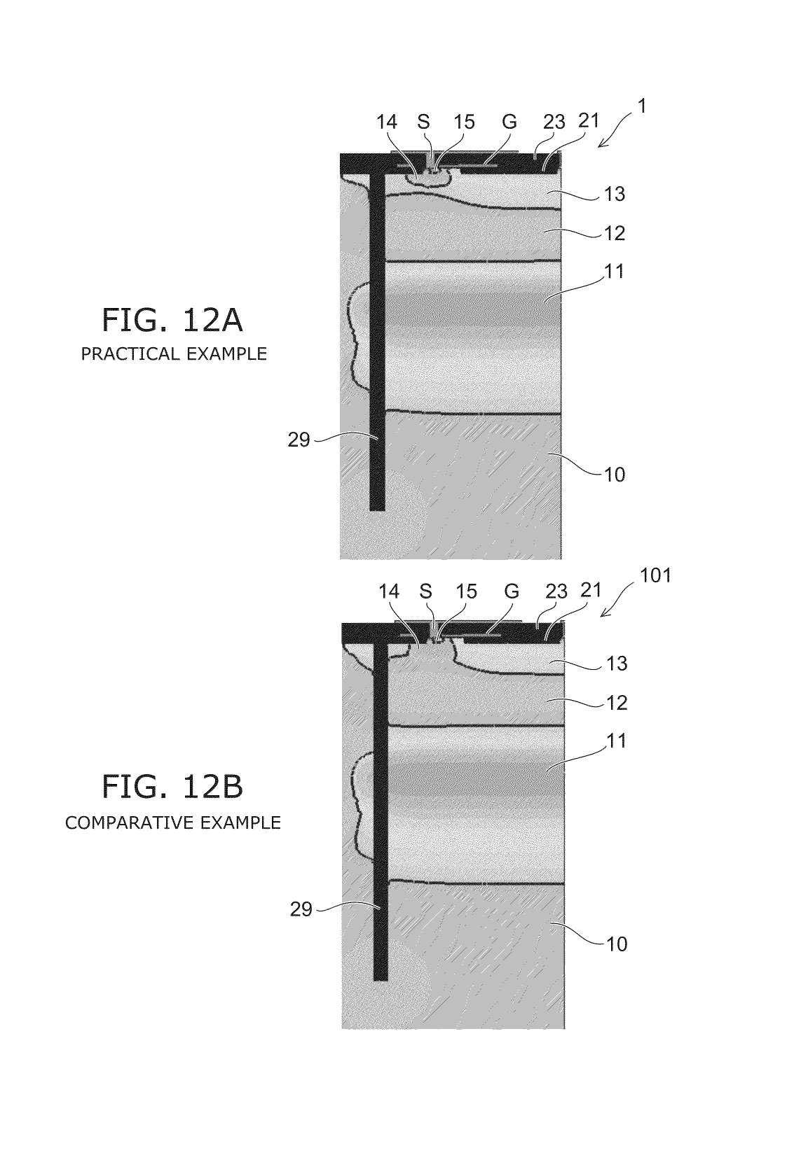

The n-type well 13, the p-type well 14, the source layer 15, the back gate layer 16, the drain layer 17, the STI 21, the gate insulating film 22, and the gate electrode G constitute an n-channel lateral DMOS (double-diffused MOSFET) 30. The region of the semiconductor portion 20 with the lateral DMOS 30 formed therein is partitioned by a DTI (deep trench isolation) 29 (see FIG. 12A) formed from the upper surface side of the semiconductor portion 20. The DTI 29 penetrates through at least the n-type well 13, the p-type RESURF layer 12 and the n-type buried layer 11, and a lower end portion thereof is disposed in the p-type substrate 10. Thereby, the DTI 29 isolates the n-type buried layer 11 and the p-type RESURF layer 12 from surrounds electrically.

The p-type RESURF layer 12 is provided in order to relax the source-drain electric field to increase the breakdown voltage of the lateral DMOS 30. The thickness of the p-type RESURF layer 12 is a thickness such that the depletion layer occurring from the pn interface between the n-type buried layer 11 and the p-type RESURF layer 12 is not in contact with the depletion layer occurring from the pn interface between the p-type RESURF layer 12 and the n-type well 13 when no potential is applied to any of the source electrode S, the drain electrode D, and the substrate electrode Sub.

Each of the n-type buried layer 11 and the p-type RESURF layer 12 is not connected to the source electrode S, the drain electrode D and the substrate electrode Sub via a semiconductor layer having the same conductivity type as itself in any direction of three dimension space. Therefore, the n-type buried layer 11 and the p-type RESURF layer 12 are in floating state. That is, the p-type RESURF layer 12 is disposed between the n-type buried layer 11, and the source electrode S and the drain electrode D. The p-type substrate 10 is disposed between the n-type buried layer 11 and the substrate electrode Sub. The n-type well 13 is disposed between the p-type RESURF layer 12, and the source electrode S and the drain electrode D. The n-type buried layer 11 is disposed between the p-type RESURF layer 12 and the substrate electrode Sub. Also, the n-type buried layer 11 and the p-type RESURF layer 12 are made be in floating state by being partitioned by the DTI 29.

Next, the operation of the semiconductor device according to the embodiment is described.

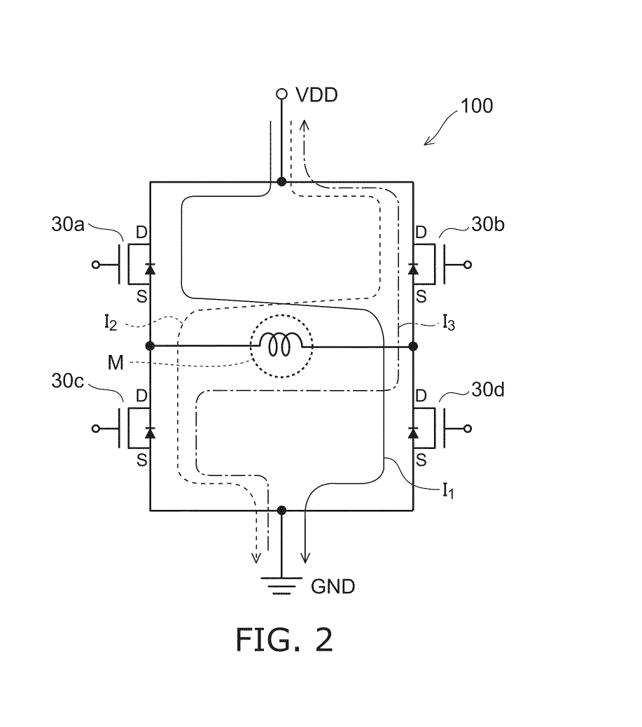

FIG. 2 is a circuit diagram illustrating an H switch including the semiconductor device according to the embodiment.

FIG. 3A is a schematic sectional view illustrating the operation of the semiconductor device according to the embodiment. FIG. 3B is an equivalent circuit diagram of FIG. 3A.

As shown in FIG. 2, the lateral DMOS 30 (see FIG. 1) formed in the semiconductor device 1 according to the embodiment is used as e.g. switching elements 30a-30d of an H switch 100 of a motor driver. The H switch 100 is a circuit for alternately supplying current of the positive phase and the negative phase to a motor M. The switching elements 30a and 30b are connected in parallel between the positive power supply potential VDD and the motor M. The switching elements 30c and 30d are connected in parallel between the motor M and the ground potential GND. For instance, the switching elements 30a-30d may be four lateral DMOS 30 formed in the same semiconductor device 1. In each lateral DMOS 30, the drain electrode D is connected on the power supply potential VDD side, and the source electrode S is connected on the ground potential GND side. The p-type substrate 10 is connected to the ground potential GND via the substrate electrode Sub (see FIG. 3A). Furthermore, a control potential is inputted to the gate electrode G.

In the H switch 100, the switching elements 30a and 30d are turned on, and the switching elements 30b and 30c are turned off. Then, a current I₁ flows in the path from the power supply potential VDD through the switching element 30a, the motor M, and the switching element 30d to the ground potential GND. Thus, the motor M is supplied with a current of the positive phase. On the other hand, the switching elements 30b and 30c are turned on, and the switching elements 30a and 30d are turned off. Then, a current I₂ flows in the path from the power supply potential VDD through the switching element 30b, the motor M, and the switching element 30c to the ground potential GND. Thus, the motor M is supplied with a current of the negative phase. Immediately after breaking the current I₁, during the period when the switching elements 30a-30d are all turned off, a regenerative current I₃ flows due to the inductance of the motor M. The regenerative current I₃ occurs so that a current having the same orientation as the current I₁ flows in the motor M. Thus, in the switching elements 30b and 30c, the current flows from the source toward the drain. This also applies to the period immediately after breaking the current I₂.

As shown in FIG. 3A, in the semiconductor device 1, a parasitic diode Di is formed at the pn interface between the p-type well 14 and the n-type well 13. Furthermore, the n-type buried layer 11, the p-type RESURF layer 12, and the n-type well 13 constitute a parasitic npn transistor T1. Moreover, the p-type substrate 10, the n-type buried layer 11, and the p-type RESURF layer 12 constitute a parasitic pnp transistor T2. Furthermore, the portion of the n-type well 13 placed between the p-type RESURF layer 12 and the p-type well 14 forms a parasitic resistance R.

Thus, an equivalent circuit C is formed among the source electrode S, the drain electrode D, and the substrate electrode Sub. In the equivalent circuit C, the anode of the parasitic diode Di is connected to the source electrode S, and the cathode is connected to the drain electrode D. The parasitic resistance R is interposed among the base of the parasitic npn transistor T1, the collector of the parasitic pnp transistor T2, and the source electrode S. The emitter of the parasitic npn transistor T1 is connected to the drain electrode D. The collector of the parasitic npn transistor T1 is connected to the base of the parasitic pnp transistor T2. The emitter of the parasitic pnp transistor T2 is connected to the substrate electrode Sub.

As shown in FIG. 3B, immediately after breaking the current I₁, due to the inductance of the motor M, the potential of the drain electrode D becomes negative relative to the source electrode S and the substrate electrode Sub. For instance, the power supply potential VDD is +40 V (volts), and the potential of the source electrode S and the substrate electrode Sub is the ground potential GND (0 V). Then, immediately after breaking the current I₁, the potential of the drain electrode D becomes e.g. −1.2 V. Thus, a forward bias is applied to the parasitic diode Di. Accordingly, a current I₃₁ flows in the path from the source electrode S through the back gate layer 16, the p-type well 14, the n-type well 13, and the drain layer 17 to the drain electrode D.

At this time, suppose that the parasitic resistance R (n-type well 13) is not interposed between the p-type well 14 and the p-type RESURF layer 12. Then, a current I₃₂ flows from the p-type well 14 into the base (p-type RESURF layer 12) of the parasitic npn transistor T1. The current I₃₂ serves as a trigger current and turns on the parasitic npn transistor T1. Thus, a current flows from the collector (n-type buried layer 11) toward the emitter (n-type well 13) of the parasitic npn transistor T1. This results in lowering the potential of the n-type buried layer 11 constituting the base of the parasitic pnp transistor T2, and turns on the parasitic pnp transistor T2. Thus, via the parasitic pnp transistor T2 and the parasitic npn transistor T1, a parasitic current I₃₃ flows in the path from the substrate electrode Sub through the p-type substrate 10, the n-type buried layer 11, the p-type RESURF layer 12, the n-type well 13, and the drain layer 17 to the drain electrode D. This results in varying the potential of the p-type substrate 10 and affects the operation of other device elements formed on the p-type substrate 10.

However, in the embodiment, the p-type well 14 and the p-type RESURF layer 12 are separated by the n-type well 13. Thus, a parasitic resistance R exists between the p-type well 14 and the p-type RESURF layer 12. Accordingly, the trigger current I₃₂ does not easily flow. The parasitic npn transistor T1 and the parasitic pnp transistor T2 are not easily turned on. Thus, the parasitic current I₃₃ does not easily flow. As a result, the variation of the potential of the p-type substrate 10 can be suppressed.

Next, a comparative example is described.

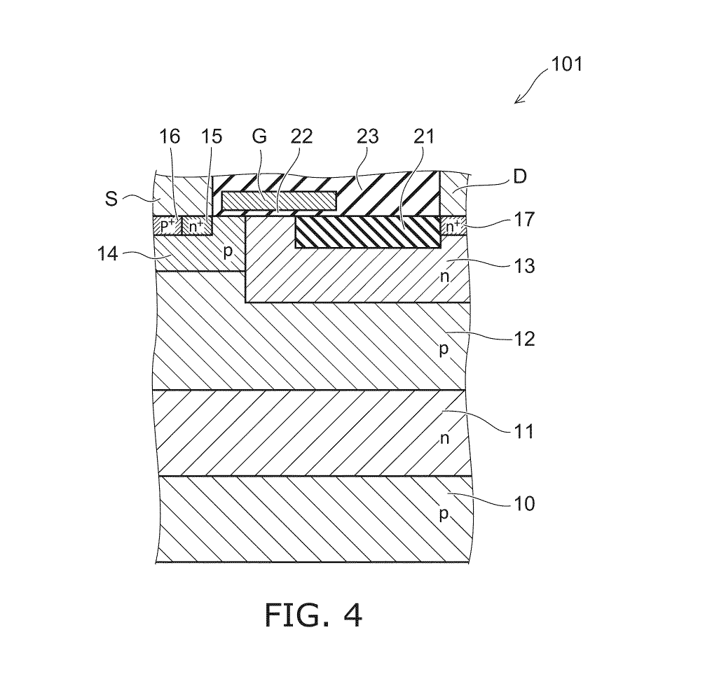

FIG. 4 is a sectional view illustrating a semiconductor device according to the comparative example.

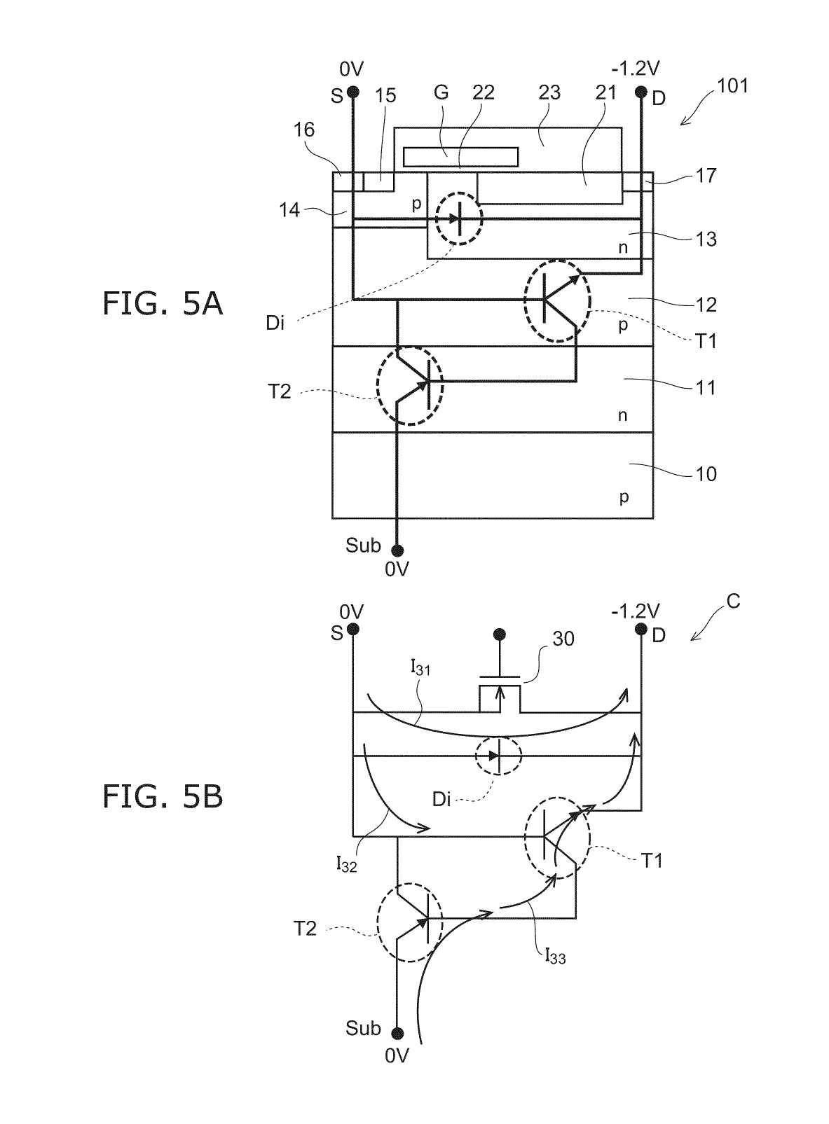

FIG. 5A is a schematic sectional view illustrating the operation of the semiconductor device according to the comparative example. FIG. 5B is an equivalent circuit diagram of FIG. 5A.

As shown in FIG. 4, in the semiconductor device 101 according to the comparative example, the p-type well 14 is in contact with the p-type RESURF layer 12. Thus, as shown in FIG. 5A, the parasitic resistance R (see FIG. 3A) is not formed between the p-type well 14 and the p-type RESURF layer 12. Accordingly, as shown in FIG. 5B, when the potential of the drain electrode D becomes negative relative to the source electrode S and the substrate electrode Sub, a current I₃₁ flows via the parasitic diode Di, and a trigger current I₃₂ easily flows from the source electrode S toward the base (p-type RESURF layer 12) of the parasitic npn transistor T1. This turns on the parasitic npn transistor T1. Thus, the potential of the n-type buried layer 11 is lowered. This turns on the parasitic pnp transistor T2. Thus, a parasitic current I₃₃ flows easily. As a result, the potential of the p-type substrate 10 is varied easily, and significantly affects the operation of other device elements. This increases the possibility of inducing malfunctions of other device elements.

Next, a second embodiment is described.

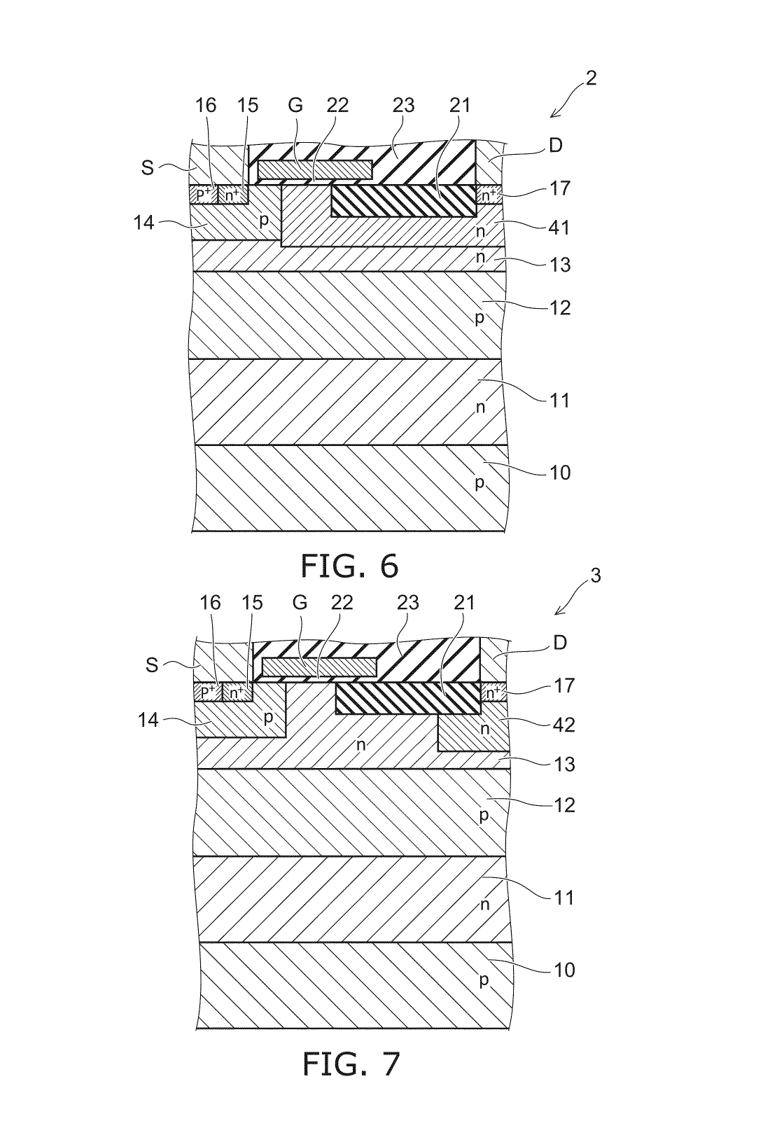

FIG. 6 is a sectional view illustrating a semiconductor device according to the embodiment.

As shown in FIG. 6, the semiconductor device 2 according to the embodiment is different from the semiconductor device 1 (see FIG. 1) according to the above first embodiment in that an n-type drift layer 41 is provided on the n-type well 13. In the semiconductor device 2, the drain layer 17 is provided on the n-type drift layer 41. The drain layer 17 is in contact with not the n-type well 13 but the n-type drift layer 41. The n-type drift layer 41 is in contact with the p-type well 14. The effective impurity concentration of the n-type drift layer 41 is higher than the effective impurity concentration of the n-type well 13, and lower than the effective impurity concentration of the drain layer 17.

According to the embodiment, an n-type drift layer 41 having a higher effective impurity concentration than the n-type well 13 is provided between the source layer 15 and the drain layer 17. Thus, the source-drain on-resistance can be made lower than that of the semiconductor device 1 (see FIG. 1) according to the above first embodiment. The configuration, operation, and effect of the embodiment other than the foregoing are similar to those of the above first embodiment.

Next, a third embodiment is described.

FIG. 7 is a sectional view illustrating a semiconductor device according to the embodiment.

As shown in FIG. 7, the semiconductor device 3 according to the embodiment is different from the semiconductor device 1 (see FIG. 1) according to the above first embodiment in that an n-type well 42 is provided on the n-type well 13. In the semiconductor device 3, the drain layer 17 is provided on the n-type well 42, and is in contact with the n-type well 42. The n-type well 42 is separated from the p-type well 14. Part of the n-type well 13 is interposed between the n-type well 42 and the p-type well 14. The effective impurity concentration of the n-type well 42 is higher than the effective impurity concentration of the n-type well 13, and lower than the effective impurity concentration of the drain layer 17.

According to the embodiment, an n-type well 42 having a higher effective impurity concentration than the n-type well 13 is provided between the source layer 15 and the drain layer 17. Thus, the source-drain on-resistance can be made lower than that of the semiconductor device 1 (see FIG. 1) according to the above first embodiment. The configuration, operation, and effect of the embodiment other than the foregoing are similar to those of the above first embodiment.

Next, a fourth embodiment is described.

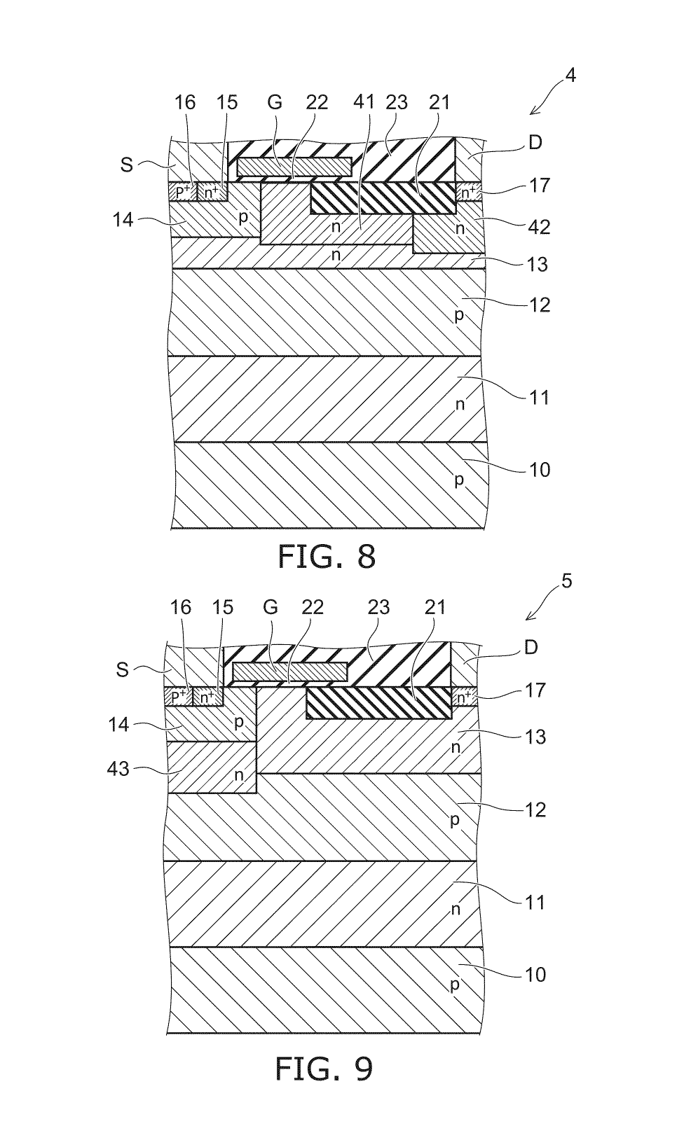

FIG. 8 is a sectional view illustrating a semiconductor device according to the embodiment.

As shown in FIG. 8, the embodiment is an example in which the second embodiment and the third embodiment described above are combined. More specifically, in the semiconductor device 4 according to the embodiment, an n-type drift layer 41 and an n-type well 42 are provided on the n-type well 13. The n-type drift layer 41 is placed between the n-type well 42 and the p-type well 14, and is in contact with the n-type well 42 and the p-type well 14. On the other hand, the n-type well 42 is separated from the p-type well 14 by the n-type drift layer 41. The drain layer 17 is provided on the n-type well 42, and is in contact with the n-type well 42. The effective impurity concentration of the n-type drift layer 41 is higher than the effective impurity concentration of the n-type well 13. The effective impurity concentration of the n-type well 42 is higher than the effective impurity concentration of the n-type drift layer 41. The effective impurity concentration of the drain layer 17 is higher than the effective impurity concentration of the n-type well 42.

According to the embodiment, an n-type drift layer 41 and an n-type well 42 are provided between the source layer 15 and the drain layer 17. Thus, the source-drain on-resistance can be made lower. The configuration, operation, and effect of the embodiment other than the foregoing are similar to those of the above first embodiment.

Next, a fifth embodiment is described.

FIG. 9 is a sectional view illustrating a semiconductor device according to the embodiment.

As shown in FIG. 9, the semiconductor device 5 according to the embodiment is different from the semiconductor device 1 (see FIG. 1) according to the above first embodiment in that an n-type buried layer 43 is provided between the p-type RESURF layer 12 and the p-type well 14. The p-type RESURF layer 12 and the p-type well 14 are separated from each other not by part of the n-type well 13 but by the n-type buried layer 43. The n-type well 13 is in contact with the p-type RESURF layer 12 and the drain layer 17.

The n-type buried layer 43 can be formed by injecting impurity serving as donor from the upper surface side of the semiconductor portion 20 by the ion implantation method. Thus, the formation depth and impurity concentration of the n-type buried layer 43 can be controlled independently of the n-type well 13. That is, the formation depth and impurity concentration of the n-type well 13 can be determined based on the required characteristics of the lateral DMOS 30. The formation depth and impurity concentration of the n-type buried layer 43 can be determined based on the required level of the parasitic resistance R. As a result, the level of the parasitic resistance R can be freely controlled. The configuration, operation, and effect of the embodiment other than the foregoing are similar to those of the above first embodiment.

Next, a sixth embodiment is described.

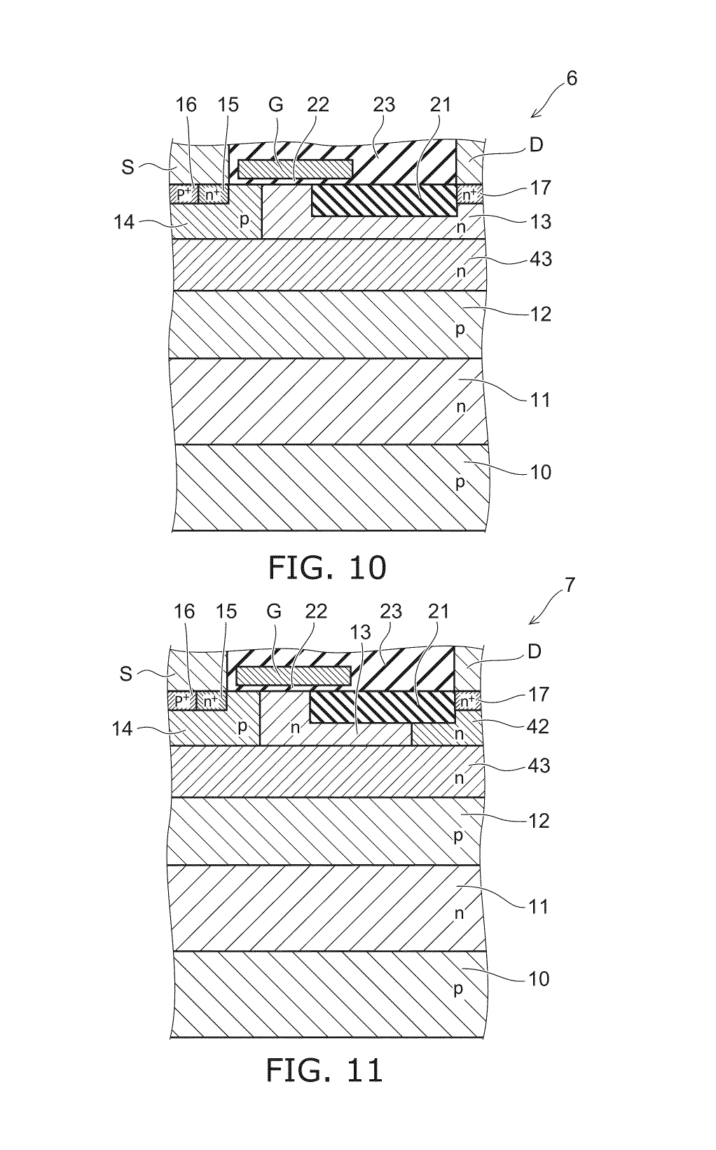

FIG. 10 is a sectional view illustrating a semiconductor device according to the embodiment.

As shown in FIG. 10, the semiconductor device 6 according to the embodiment is different from the semiconductor device 5 (see FIG. 9) according to the above fifth embodiment in that the n-type buried layer 43 is placed also between the p-type RESURF layer 12 and the n-type well 13. That is, the n-type well 13 is placed on the n-type buried layer 43. The drain layer 17 is in contact with the n-type well 13.

Thus, by appropriately controlling the impurity concentration of the n-type buried layer 43, the parasitic resistance R (see FIG. 3B) between the p-type well 14 and the p-type RESURF layer 12 can be made higher. Accordingly, the parasitic current I₃₃ (see FIG. 3B) can be further reduced. The configuration, operation, and effect of the embodiment other than the foregoing are similar to those of the above fifth embodiment.

Next, a seventh embodiment is described.

FIG. 11 is a sectional view illustrating a semiconductor device according to the embodiment.

As shown in FIG. 11, the semiconductor device 7 according to the embodiment is different from the semiconductor device 6 (see FIG. 10) according to the above sixth embodiment in that an n-type well 42 is provided on part of the n-type buried layer 43. The effective impurity concentration of the n-type well 42 is higher than the effective impurity concentration of the n-type well 13. The n-type well 42 is separated from the p-type well 14 by the n-type well 13. The drain layer 17 is placed on the n-type well 42, and is in contact with the n-type well 42.

According to the embodiment, an n-type well 42 having a higher effective impurity concentration than the n-type well 13 is provided between the source layer 15 and the drain layer 17. Thus, the source-drain on-resistance can be made lower than that of the semiconductor device 6 (see FIG. 10) according to the above first embodiment. The configuration, operation, and effect of the embodiment other than the foregoing are similar to those of the above sixth embodiment.

Next, a test example is described.

FIGS. 12A and 12B illustrate simulation results of the impurity concentration distribution formed in the semiconductor device. FIG. 12A shows a practical example, and FIG. 12B shows a comparative example.

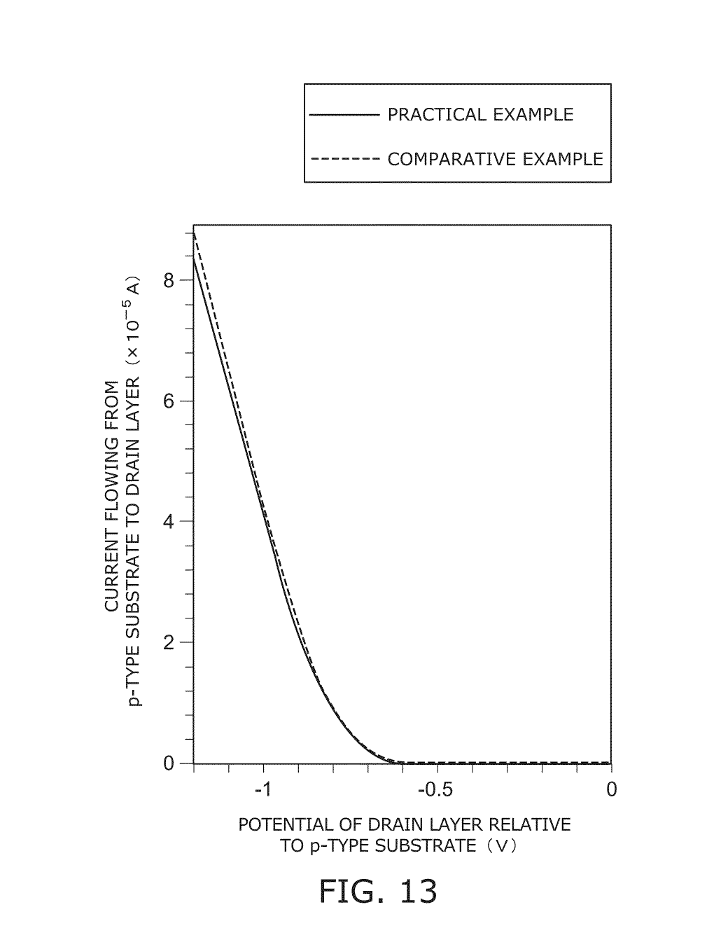

FIG. 13 is a graph illustrating the simulation results of I-V characteristics. The horizontal axis represents the potential of the drain layer relative to the p-type substrate. The vertical axis represents the magnitude of current flowing from the p-type substrate to the drain layer.

As shown in FIGS. 12A and 12B, in the test example, computer simulation was used to calculate the impurity concentration distribution in the case of manufacturing semiconductor devices according to the practical example and the comparative example by the ion implantation method and the like. The semiconductor device according to the practical example was a device having a configuration similar to that of the semiconductor device 1 (see FIG. 1) according to the above first embodiment. The semiconductor device according to the comparative example was a device having a configuration similar to that of the semiconductor device 101 (see FIG. 4) according to the above comparative example. The magnitude of the parasitic current I₃₃ (see FIGS. 3B and 5B) flowing in these semiconductor devices was calculated.

As shown in FIG. 13, the potential of the drain layer 17 relative to the potential of the p-type substrate 10 was set to −1.2 V. Then, the magnitude of the parasitic current I₃₃ flowing in the semiconductor device according to the practical example was 8.46×10⁻⁵ A (ampere). The magnitude of the parasitic current I₃₃ flowing in the semiconductor device according to the comparative example was 8.94×10⁻⁵ A. Thus, in the practical example, the magnitude of the parasitic current I₃₃ flowing from the p-type substrate 10 to the drain layer 17 was successfully made lower by approximately 5.3% than in the comparative example.

In the examples illustrated in the above embodiments, the semiconductor device constitutes a switching element of an H switch of a motor driver. However, the embodiments are not limited thereto. The semiconductor device according to the above embodiments can be suitably applied to e.g. an output circuit with high breakdown voltage in an analog power integrated circuit.

The embodiments described above can realize a semiconductor device in which the parasitic current flowing in the semiconductor substrate is suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

1. A semiconductor device comprising:
a semiconductor substrate of a first conductivity type;
a first semiconductor layer of a second conductivity type provided on the semiconductor substrate, the first semiconductor layer being in floating state;
a second semiconductor layer of the first conductivity type provided on the first semiconductor layer, the second semiconductor layer being in floating state;
a first well of the second conductivity type provided on the second semiconductor layer;
a second well of the first conductivity type provided on part of the first well;
a source layer of the second conductivity type provided on part of the second well and separated from the first well;
a back gate layer of the first conductivity type provided on another part of the second well;
a drain layer of the second conductivity type provided on another part of the first well;
a gate insulating film provided immediately above a portion of the second well between the first well and the source layer;
a gate electrode provided on the gate insulating film;
a source electrode connected to the source layer and the back gate layer;
a drain electrode connected to the drain layer; and
a substrate electrode connected to the semiconductor substrate,
the second semiconductor layer and the second well being separated from each other by the first well.

2. The device according to claim 1, wherein the drain layer is in contact with the first well.

3. The device according to claim 1, further comprising:
a drift layer provided on the first well, being in contact with the second well, being of the second conductivity type, and having a higher effective impurity concentration than that of the first well,
wherein the drain layer is disposed on the drift layer and is in contact with the drift layer.

4. The device according to claim 1, further comprising:
a third well provided on the first well, separated from the second well, being of the second conductivity type, and having a higher effective impurity concentration than that of the first well,
wherein the drain layer is disposed on the third well and is in contact with the third well.

5. The device according to claim 1, further comprising:
a drift layer provided on the first well, being of the second conductivity type, and having a higher effective impurity concentration than that of the first well; and
a third well provided on the first well, being of the second conductivity type, and having a higher effective impurity concentration than that of the drift layer,
wherein the third well is in contact with the drift layer and is separated from the second well by the drift layer, and
the drain layer is disposed on the third well and is in contact with the third well.

6. The device according to claim 1, further comprising:
a deep trench isolation penetrating through the first well, the second semiconductor layer and the first semiconductor layer, a lower end portion of the deep trench isolation being disposed in the semiconductor substrate, and the deep trench isolation isolating electrically the first semiconductor layer and the second semiconductor layer from surrounds.

7. The device according to claim 1, wherein the device constitutes a switching element of an H switch of a motor driver.

8. A semiconductor device comprising:
a semiconductor substrate of a first conductivity type;
a first semiconductor layer of a second conductivity type provided on the semiconductor substrate, the first semiconductor layer being in floating state;
a second semiconductor layer of the first conductivity type provided on the first semiconductor layer, the second semiconductor layer being in floating state;
a third semiconductor layer of the second conductivity type provided on the second semiconductor layer;
a first well of the second conductivity type provided on the second semiconductor layer;
a second well of the first conductivity type provided on the third semiconductor layer;
a source layer of the second conductivity type provided on part of the second well and separated from the first well;
a back gate layer of the first conductivity type provided on another part of the second well;
a drain layer of the second conductivity type provided on the first well;
a gate insulating film provided immediately above a portion of the second well between the first well and the source layer;
a gate electrode provided on the gate insulating film;
a source electrode connected to the source layer and the back gate layer;
a drain electrode connected to the drain layer; and
a substrate electrode connected to the semiconductor substrate,
the second semiconductor layer and the second well being separated from each other by the third semiconductor layer.

9. The device according to claim 8, wherein the first well is in contact with the drain layer and the second semiconductor layer.

10. The device according to claim 8, wherein the first well is disposed on the third semiconductor layer, and the drain layer is in contact with the first well.

11. The device according to claim 8, further comprising:
a third well provided on part of the third semiconductor layer, being of the second conductivity type, and having a higher effective impurity concentration than that of the first well,
wherein the first well is disposed on the third semiconductor layer between the second well and the third well, and
the drain layer is in contact with the third well.

12. The device according to claim 8, further comprising:
a deep trench isolation penetrating through the first well, the second semiconductor layer and the first semiconductor layer, a lower end portion of the deep trench isolation being disposed in the semiconductor substrate, and the deep trench isolation isolating electrically the first semiconductor layer and the second semiconductor layer from surrounds.

13. The device according to claim 8, wherein the device constitutes a switching element of an H switch of a motor driver.

14. A semiconductor device comprising:
a semiconductor substrate of p-type;
a first semiconductor layer of n-type provided on the semiconductor substrate, the first semiconductor layer being in floating state;
a second semiconductor layer of p-type provided on the first semiconductor layer, the second semiconductor layer being in floating state;
a first well of n-type provided on the second semiconductor layer;
a second well of p-type provided on part of the first well;
a source layer of n-type provided on part of the second well and separated from the first well;
a back gate layer of p-type provided on another part of the second well;
a drain layer of n-type provided on another part of the first well and being in contact with the first well;
a gate insulating film provided immediately above a portion of the second well between the first well and the source layer;
a gate electrode provided on the gate insulating film;
a source electrode connected to the source layer and the back gate layer;
a drain electrode connected to the drain layer;
a substrate electrode connected to the semiconductor substrate; and
a deep trench isolation penetrating through the first well, the second semiconductor layer and the first semiconductor layer, a lower end portion of the deep trench isolation being disposed in the semiconductor substrate, and the deep trench isolation isolating electrically the first semiconductor layer and the second semiconductor layer from surrounds,
the second semiconductor layer and the second well being separated from each other by the first well, and
the device constituting a switching element of an H switch of a motor driver.
